(19) United States
(12) Patent Application Publication
(10) Pub. No.: US 2009/0011522 A1
(43) Pub. Date: Jan. 8, 2009

(54) Semiconductor Device Package Disassembly

(76) Inventors: Monte D. Drennan, (US); Derek Laughlin, (US)

Correspondence Address: Michael T. Konczal, P.O. Box 863656, Plano, TX, 75086, US

(21) Appl. No.: 11/772,627

(22) Filed: Jul. 2, 2007

(51) Int. Cl. H01L 21/50; B23K 26/00

(52) U.S. Cl. 438/4; 219/121.68; 219/121.69; 257/E21.499

(57) ABSTRACT

Systems and methods are disclosed for the disassembly and preferably reassembly of semiconductor device packages. A method of the invention includes steps for excavating a portion of a semiconductor device package to expose a target surface within the interior of the package. The technique further includes steps of focusing a laser at a selected distance from the target surface in order to ablate the package material, exposing the target surface. Preferred embodiments of the invention are disclosed in which a cavity is excavated through the package to expose portions of leadfingers within. A temporary chip mount plate is affixed to an exterior surface of the package to cover one side of the cavity. A chip is attached to the temporary chip mount plate where it is electrically coupled to the leadfingers in the interior of the package. The contents of the cavity are then encapsulated with dielectric mold compound and the temporary chip mount plate is preferably removed to expose the backside of the chip.

### TECHNICAL FIELD

The invention relates to electronic semiconductor device testing and analysis. More particularly, the invention relates to methods and systems for the disassembly of microelectronic semiconductor packages and also to the reassembly of such packages.

### BACKGROUND OF THE INVENTION

Integrated circuit testing and analysis is an important part of semiconductor device design and manufacturing processes. It provides information necessary for design evaluation and for taking corrective action to improve quality and reliability. Failure analysis is useful in developing improved designs, shortening product development cycles, and reducing costs.

Various non-destructive analytical techniques such as photo emission, Scanning Optical Microscopes (SOM), Thermally Induced Voltage Alteration (TIVA), and Light Induced Voltage Alteration (LIVA), are often used in the microelectronics arts. Light emission analysis is often employed for localizing many types of common defects, such as interconnection short and open circuits, gate oxide shorts, and degraded p-n junctions. Light emission microscopy localizes light-emitting regions of biased IC's. Energetic (“hot”) carrier production and subsequent energy release results in the generation of photons with energies in the near infra-red and visible wavelengths. This permits emitted photons to be observed. One problem with this procedure, however, is that the photons may become blocked by opaque layers within the chip. Scanning Optical Microscopy (SOM) is sometimes used to gain information relating to the functioning of ICs, providing resolution, contrast, and depth of focus that are improved over conventional microscopy, but which can nevertheless be obscured by the multiple layers of an IC package. LIVA (Light Induced Voltage Alterations) and TIVA (Thermally Induced Voltage Alterations) are often used for fault isolation. TIVA locates ohmic shorts by monitoring the large resistance change that occurs at most shorts upon heating. A problem with LIVA and TIVA techniques is the need for constant current biasing of the device under test. Nearly all integrated circuits require constant source voltage for correct operation. Another problem is noise levels, which can obscure the weak signals produced by these techniques, particularly when shielded by the backside of the chip.

Non-destructive failure analysis is desirable, but is not always practical. Backside analysis is often critical, particularly for “flip-chip” packages and for devices with multiple metal layers, which obscure visibility of crucial chip and package components from the topside. Examples of such packages include Thin Quad Flat-Pack (TQFP), Small Outline Integrated Circuits (SOIC), Dual In-line Packages (DIP), Pin Grid Arrays (PGA), among others. Due to the inaccessibility of the backside of the IC chip in many packages, it is often necessary to perform analysis techniques that are destructive. Cutting and probing processes allow analysts to trace electrical signals in IC's to determine the behavior of the circuitry. Techniques for the mechanical and chemical removal of material are often used to expose the interior of a package or the layers of an IC. Cross-sectioning is another approach that allows analysts to view a “slice” of a package or an IC. Cross-sectioning is typically performed by mechanical grinding. The device under test is ground perpendicular to the surface until the feature of interest is exposed. Great care must be taken to preserve the shape of metals and surface features and to yield a relatively in-tact surface for analysis, making cross-sectioning difficult and expensive.

It is also known in the arts to disassemble a completed plastic semiconductor device package in order to reassemble it with a new IC inside. Material is removed from an existing package in order to expose portions of the leadfingers within. An IC is then electrically connected to the leadfingers and encapsulated. Such reconstructed packages are useful for testing, failure analysis, design verification, prototyping, the placement of new hardware in an established circuit, and possibly other applications. Problems are encountered in package disassembly and reassembly techniques known in the arts. One general class of problems relates to the disassembly process. It is essential to expose the leadfingers within the package with minimal damage in order to facilitate the attachment of operable electrical connections to the new chip. Exposure of the leadfingers entails the removal of encapsulant materials, and possibly other materials, such as a multi-layer semiconductor chip and metal mount pad, depending upon the structure of the particular package and application. Techniques known in the arts for removing such material include mechanical grinding, drilling, sand blasting, chemical etching, and plasma etching. These techniques are applied in various combinations and with various degrees of precision. Removal of material in contact with the surface of leadframes without damage to the underlying metal is particularly problematic. Such techniques are sometimes expensive, cumbersome, somewhat hit-or-miss in terms of success, or simply incapable of reliably providing the desired results. The reassembly of a package with a new IC inside poses an additional set of problems. Reassembly requires several steps including mounting a chip within a cavity formed during disassembly, making suitable electrical connections, and resealing the package with curable mold compound. Efforts exerted in a successful disassembly can be wasted due to problems encountered in the reassembly process, such as limitations imposed by pre-existing mount pad geometry or by steps taken to prevent or remove flashing produced during encapsulation.

Due to these and other technical challenges, improved semiconductor package disassembly and reassembly techniques would be useful and advantageous in the arts. The present invention is directed to overcoming, or at least reducing the effects of, one or more of the problems described above.

### SUMMARY OF THE INVENTION

In carrying out the principles of the present invention, in accordance with preferred embodiments thereof, the invention provides methods for disassembling a semiconductor package and methods for reassembling the package with a new semiconductor chip installed within. Preferred embodiments of the invention may be practiced in the context of installing chips in disassembled “dummy” packages, or in the disassembly, removal, and replacement of chips in fully functional “live” packages.

According to one aspect of the invention, a method for packaging a semiconductor chip includes initial steps of removing package material from an existing package in order to excavate a cavity through the package to expose a mount pad and portions of leadfingers within. The mount pad is removed from the package. In a further step, a temporary chip mount plate is affixed to an exterior surface of the package to cover one side of the cavity. A chip is attached, inside the cavity, to the temporary chip mount plate. The chip mounted within the cavity is electrically coupled to the leadfingers in the interior of the package, and the couplings are encapsulated with dielectric mold compound. The temporary chip mount plate is then removed to expose the backside of the chip.

According to another aspect of the invention, in an example of a preferred embodiment of a method of disassembling a semiconductor package according to the invention, package material is removed using a laser.

According to another aspect of the invention, preferred embodiments of methods of dissembling a package include steps for removing package material using a laser focused a selected distance from the leadframe.

According to yet another aspect of the invention, methods for disassembling a semiconductor package include steps for removing package material whereby a cavity is excavated through the package. Exemplary preferred embodiments of the invention include steps for the removal of a chip from the interior of the package.

According to another aspect of the invention, a method of excavating a portion of a semiconductor device package to expose a target surface within the interior of the package includes steps for focusing the cutting beam of a laser at a selected distance from the target surface in order to ablate the package material to expose the target surface.

According to still another additional aspect of the invention, a system for excavating a portion of a semiconductor device package to expose a target surface within the interior of the package includes a mechanism for securing a semiconductor device package, and a laser for focusing at selected distances from the target surface of a secured semiconductor device package.

The invention has advantages including but not limited to one or more of the following: providing systems and methods for disassembling semiconductor device packages; providing systems and methods for manufacturing reconstructed package assemblies; and reducing costs associated with package testing and analysis. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top view of an example of a semiconductor package illustrating method steps according to a preferred embodiment of the invention;

FIG. 2 is a bottom view of an example of a semiconductor package illustrating method steps according to a preferred embodiment of the invention;

FIG. 3 is a side view of an example of a semiconductor package illustrating method steps according to a preferred embodiment of the invention;

FIG. 4 is a bottom view of an example of a semiconductor package illustrating method steps according to a preferred embodiment of the invention;

FIG. 5 is a cutaway side view of an example of a semiconductor package undergoing method steps according to a preferred embodiment of the invention;

FIG. 6 is a cutaway side view of an example of a preferred embodiment of a semiconductor package prepared according to methods of the invention; and

FIG. 7 is a simplified schematic view of an example of a system for semiconductor package disassembly according to a preferred embodiment of the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

The invention provides improved testing and analysis for semiconductor device development and manufacturing. Systems and methods of the invention use lasers for package disassembly and temporary chip mount plates for package reassembly.

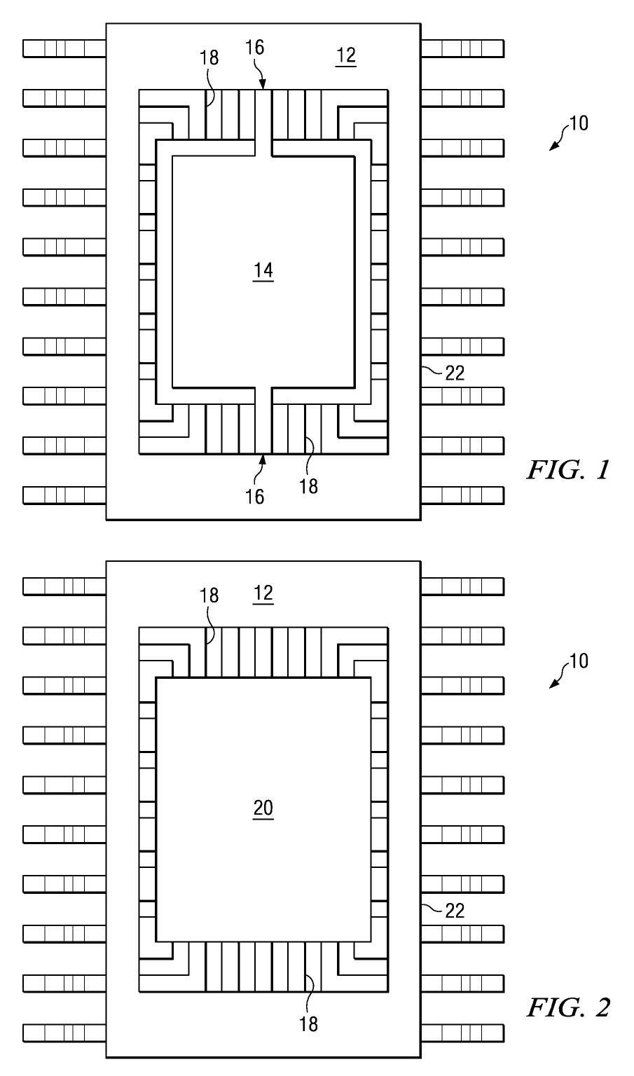

First referring primarily to FIG. 1, a top view of a semiconductor package 10 is shown for the purpose of illustrating steps in an exemplary embodiment of methods for opening a semiconductor package and placing a chip therein. Package material, primarily encapsulant 12, is removed in order to expose the chip mount pad 14 and portions of the leadframe 16, i.e. leadfingers 18, contained within. Preferably, the package 10 is a plastic injection molded dummy part containing no chip or connecting bond wires, although the invention may also be practiced with a live package containing a chip mounted on the mount pad and electrically connected with the leadfingers. In practicing the invention, the material to be removed from the package may preferably be removed using mechanical techniques, such as grinding for example, to within a short distance of the target surface, e.g., about 10-100 microns, depending on the type of materials, e.g. mold compound, chips, bondwires. The step of removing the package material 12 adjacent to the leadfingers 18 is then preferably performed by ablating with a laser, providing an in tact surface. In the presently preferred embodiment of the invention, a neodymium-doped vanadium aluminum garnet laser, also called a Nd:VAG laser, is used, although other industrial lasers suitable for cutting may also be used without departure from the invention.

The package material 12 is excavated sufficiently to expose the mount pad 14 originally within the package 10. Typically, the package material 12 is removed in order to excavate a cavity 20 extending entirely through the package 10. The excavation of the cavity 20 preferably exposes a portion of a plurality of leadfingers 18 in the interior of the package 10, as well as the chip mount pad 14. The chip mount pad 14 is severed from the leadframe 16 and is removed from the package 10. The package 10 thus prepared preferably has a configuration as depicted in FIG. 2, with the cavity 20 extending through the package 10 and the sidewall 22 integrity of the package preferably remaining undisturbed.

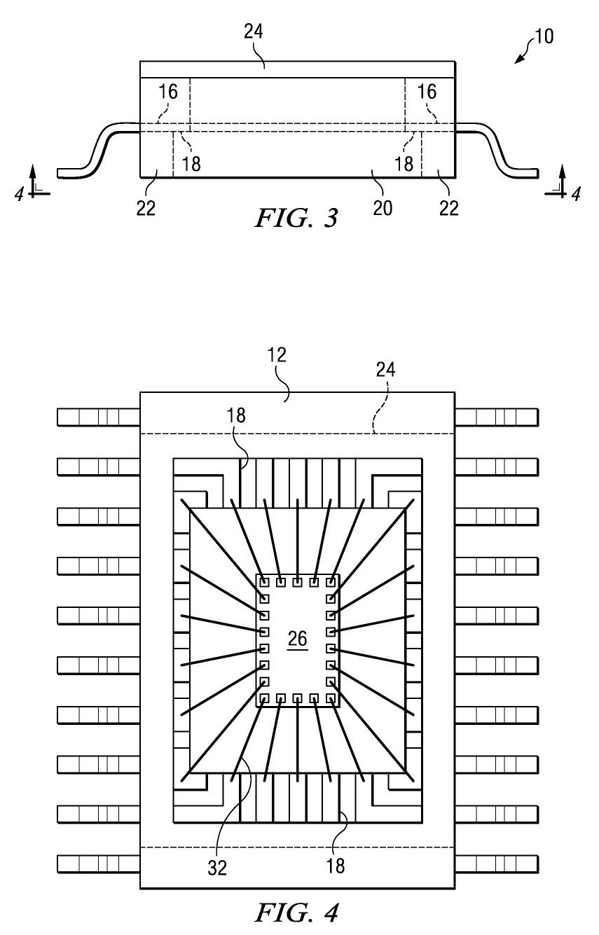

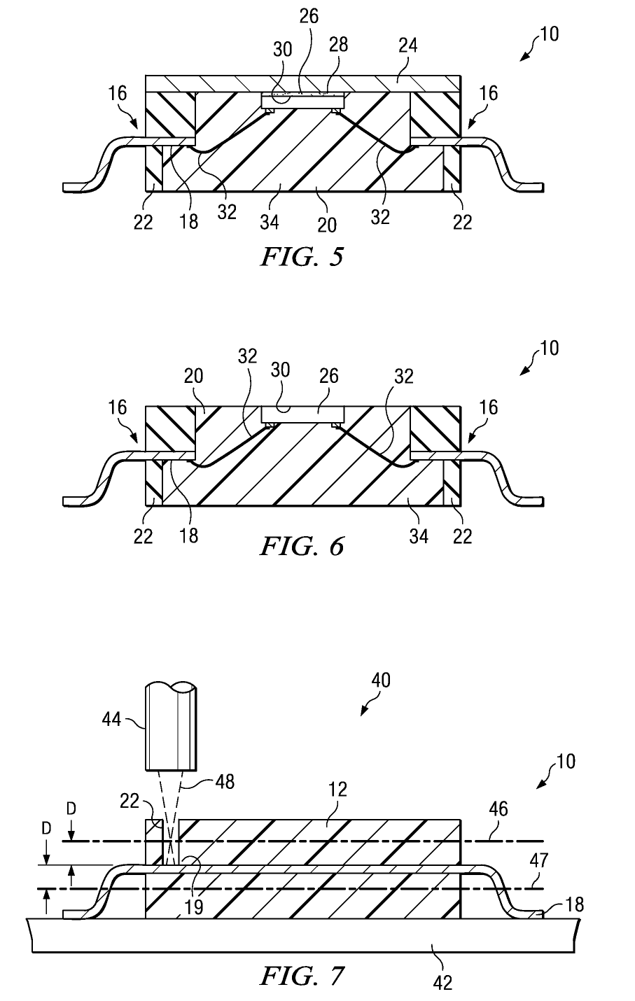

FIG. 3 presents a side view of a semiconductor package 10 with a temporary chip mount plate 24 affixed to an exterior surface of the package 10 on a plane defined by the sidewalls 22. As shown, one side of the cavity 20 is entirely enclosed by the temporary chip mount plate 24, which is preferably made from a sheet of metal such as aluminum. Now referring primarily to FIG. 4, a chip 26 is positioned within the cavity 20 and attached to the temporary chip mount plate 24, preferably using curable chip mount adhesive 28 (FIG. 5) on the back surface 30 (FIG. 5) of the chip 26. The chip 26 attached to the temporary chip mount plate 24 is electrically connected, preferably using gold wirebonds 32, to numerous leadfingers 18 in the interior of the package 10. As shown in FIG. 5, the chip 26, wirebonds 32, and exposed leadfingers 18 within the cavity 20 are encapsulated. Preferably, the cavity 20 is filled or substantially filled with dielectric mold compound 24 such as curable plastic or epoxy resin familiar in the arts. Subsequently, as shown in FIG. 6, the temporary chip mount plate 24 is preferably removed to expose the back surface 30 of the chip 26. The temporary chip mount plate 24 may be removed by grinding, sandblasting, abrading, polishing, or laser ablating, or some combination of such techniques suitable for exposing the surface 30 of the chip 26 for purposes of testing and analysis.

Now referring primarily to FIG. 7, a simplified schematic overview of a preferred embodiment of a system 40 for the disassembly of a semiconductor device package 10 is shown. The workpiece 10, in this case a cutaway side view of a DIP package is shown for the sake of example, is securely held on a cutting table 42. A laser 44, preferably a Nd:VAG laser including associated suitable power sources and control mechanisms, is brought to bear on the package material to be removed in the disassembly of the package 10. As shown, the high-intensity cutting, vaporizing, and/or ablating beam 48 generated by the laser 44 is focused, not on the metal surface 19 of the package 10, in this case the surface 19 of a leadframe 18, but on a parallel plane a selected distance from the target surface, as indicated by the line 46. Preferably, the plane of focus 46 is oriented parallel to the surface to be exposed, in this case the leadframe surface 19, a distance within a selected range, indicated by D. The value of D is selected in order to remove the package material, e.g. encapsulant 12, necessary to expose the target surface, e.g. leadframe surface 19, without significant damage. It should be understood that a plane of focus, e.g. as shown by line 47, beyond the target surface 19 may also be used. In the presently preferred embodiment of the invention, using a commercially available Nd:VAG laser, it has been found that distance D within the range of about 8 to 12 millimeters may be used for disassembling a range of common molded plastic packages. The target surface, once exposed, may be cleaned and bonded using techniques known in the arts, such as etching or polishing. The systems 40 of the invention can be used to excavate the various types of package material intervening between the exterior of a common package and the leadframe, such as mold compound, adhesives, and semiconductor chips. The invention may be practiced with various materials in numerous applications such as, but not limited to, the excavation of entire packages, chips, or portions of chips. Target surfaces may also include bond pads, bondwires, leadfingers, selected chip layers, or other surfaces, so long as the plane of focus is maintained a suitable distance D from the target surface, e.g., leadframe surface 19 in FIG. 7. Preferably, in order to maximize cutting ability while avoiding overheating, the laser is applied in pulses adapted to the package thickness and materials. In preferred embodiments, the laser may be applied in order to ablate material in alternating lines, in order to control heating. The power level and exposure time of the laser are preferably adapted according to operational parameters such as package composition and geometry. The use of the laser as described for practicing the invention advantageously removes material quickly and precisely without significant damage to the metal finish of the target surface. Additionally, the laser removal of package material may be used to provide sidewalls during disassembly adapted to facilitate encapsulation upon reassembly. In alternative embodiments, other types of lasers such as Nd:YAG or CO₂ lasers may be used. Also, cooling mechanisms, such as the application of liquid nitrogen, may be used as needed, along with variable power levels, pulsing, and ablation patterns, to control the temperature of the target surface and surrounding material according to the operational characteristics of the laser.

It should be appreciated by those skilled in the arts that the invention may also be practiced in alternative embodiments by providing a pre-formed package 10, as illustrated in FIG. 3 and FIG. 4, having a temporary mounting plate 24 covering one side of a through-cavity 20. In such embodiments of the invention, providing a package thus prepared permits the omission of the steps relating to the removal of package material. A chip 26 may then be mounted, as shown in, and described with respect to FIG. 4, and the further steps of encapsulating and exposing the back side of the chip 26 may subsequently be implemented as described and portrayed herein. In another alternative embodiment of the invention, the temporary mounting plate may be left in place, for example, in applications in which the primary objective is to emplace a chip within the package footprint and where access to the backside of the chip is not desired.

The methods and systems of the invention provide one or more advantages including but not limited to; providing access to the interior of semiconductor device packages for analysis and testing, providing access to the backside of chips in reassembled packages; reducing failure analysis and design debugging costs, and providing repackaging capabilities. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

We claim:

1. A method of excavating a portion of a semiconductor device package to expose a target surface within the interior of the package, the method comprising the steps of:
focusing the cutting beam of a laser at a selected distance from the target surface; and
energizing the cutting beam focused at the selected distance in order to ablate the package material, whereby the target surface becomes exposed.

2. A method according to claim 1 wherein removing package material further comprises ablating package material using a Nd:VAG laser.

3. A method according to claim 1 further comprising ablating package material using a cutting beam focused within the range of approximately 8 to 12 millimeters from the target surface.

4. A method according to claim 1 further comprising ablating package material using a pulsed cutting beam focused within the range of approximately 8 to 12 millimeters from the target surface.

5. A method according to claim 1 further comprising ablating package material using a pulsed cutting beam focused within the range of approximately 8 to 12 millimeters in front of the target surface.

6. A method according to claim 1 further comprising ablating package material using a pulsed cutting beam focused within the range of approximately 8 to 12 millimeters beyond the target surface.

7. A method according to claim 1 wherein the target surface comprises a portion of a metallic leadframe.

8. A method according to claim 1 wherein the target surface comprises a mount pad.

9. A method according to claim 1 wherein the target surface comprises a portion of a bond wire.

10. A method according to claim 1 wherein the target surface comprises a portion of a semiconductor chip.

11. A system for excavating a portion of a semiconductor device package for exposing a target surface within the interior of the package, the system comprising:
a mechanism for securing a semiconductor device package for excavation; and
a laser focusable at selected distances from the target surface of a secured semiconductor device package, wherein the planar position of the laser is adjustable with respect to the target surface.

12. A system according to claim 11 wherein the laser further comprises a Nd:VAG laser.

13. A method for packaging a semiconductor chip in a semiconductor device package comprising the steps of:
removing package material to expose a portion of a leadframe contained within the package;
whereby a cavity is excavated through the package and exposing a mount pad and portions of a plurality of leadfingers in the interior of the package;
removing the mount pad from the package;
attaching a temporary chip mount plate to an exterior surface of the package whereby one side of the cavity is covered by the temporary chip mount plate;
positioning a chip within the cavity and attaching the chip to the temporary chip mount plate;
operably coupling the chip positioned within the cavity with a plurality of the leadfingers in the interior of the package;
encapsulating the chip and operable couplings with dielectric material; and
removing the temporary chip mount plate to expose the back side of the chip.

14. A method according to claim 13 wherein removing package material further comprises ablating package material using a laser.

15. A method according to claim 13 wherein removing package material further comprises ablating package material using a Nd:VAG laser.

16. A method according to claim 13 wherein removing package material further comprises ablating package material using a laser focused a selected distance from the leadframe.

17. A method according to claim 13 wherein removing package material further comprises ablating package material using a laser focused a selected distance from the leadframe.

18. A method according to claim 13 wherein removing package material further comprises ablating package material using a laser focused within the range of approximately 8 to 12 millimeters from the leadframe.

19. A method according to claim 13 wherein removing package material further comprises ablating package material using a pulsed laser.

20. A method according to claim 13 wherein, removing package material whereby a cavity is excavated through the package, further comprises removing a chip from the package.
